(19) United States
(12) Patent Application Publication
(10) Pub. No.: US 2020/0102948 A1
(43) Pub. Date: Apr. 2, 2020

(54) RECIPROCATING PUMP

(71) Applicant: IWAKI CO., LTD., Tokyo (JP)

(72) Inventors: Shigeyoshi MATSUO, Sayama-shi (JP); Hiroyuki TANABE, Sayama-shi (JP); Motohiro TANAKA, Sayama-shi (JP)

(73) Assignee: IWAKI CO., LTD., Tokyo (JP)

(21) Appl. No.: 16/259,082

(22) Filed: Jan. 28, 2019

(30) Foreign Application Priority Data
Sep. 27, 2018 (JP) 2018-182025

(51) Int. Cl. F04B 43/067; F04B 43/073; F04B 49/22; F04B 53/06; H01L 21/67

(52) U.S. Cl. CPC F04B 43/067; F04B 43/0733; F04B 53/16; F04B 53/06; H01L 21/67023; F04B 49/22

(57) ABSTRACT

A reciprocating pump includes: a pump head having an inner space; a diaphragm configured to partition the inner space of the pump head into a pump chamber into which a transfer fluid is to be introduced and a working chamber into which working air is to be introduced; a driving device including a reciprocating member coupled to the diaphragm, the driving device being capable of driving the reciprocating member with the working air at least in a direction that the diaphragm is retracted; and a working air switching device.

### CROSS-REFERENCE TO RELATED APPLICATIONS

This application is based upon and claims the benefit of priority from the prior Japanese Patent Application No. 2018-182025, filed on Sep. 27, 2018, the entire contents of which are incorporated herein by reference.

### BACKGROUND OF THE INVENTION

### Field of the Invention

The present invention relates to a reciprocating pump.

### Description of the Related Art

A reciprocating pump is known which causes a diaphragm to reciprocate. For example, as one example of the reciprocating pump, a resist pump is known which is used in applying a resist by coating to the upper surface of a semiconductor wafer by a spin coating method at a former stage in a step of exposing the semiconductor wafer (see Japanese Patent Laid-Open No. 2006-352002, for example). To prevent the generation of air bubbles, this resist pump is configured such that the discharge amount of a resist is set larger than that in a pump which feeds a resist to a nozzle at a constant flow rate.

However, the resist pump disclosed in the above-mentioned Japanese Patent Laid-Open No. 2006-352002 feeds a resist by causing a diaphragm, which changes the volume of a resist chamber (pump chamber), to be displaced by advancing and retracting the diaphragm by a constant amount with an air cylinder. In the case of the reciprocating pump of this type, only the center portion of the diaphragm is advanced and retracted. Accordingly, the outer peripheral portion of the diaphragm is deformed due to the influence caused by a load determined by a discharge pressure and viscosity of a liquid and hence, the linearity cannot be ensured between a stroke length of the center portion of the diaphragm and a discharge amount or an amount of volume change. Therefore, a complicated control or structure is required to discharge a liquid of a constant amount or a constant pressure.

On the other hand, it can be also considered that a diaphragm is directly driven with air without using an air cylinder. In this case, however, a device which generates a negative pressure is required in a sucking step. In the case where an ejector is used, it is necessary to continuously discharge air during the sucking operation and hence, a consumption amount of air is increased. When the diaphragm is always biased in one direction by a spring back method, a differential pressure is generated between the front and rear of the diaphragm so that there is a problem that the diaphragm is required to have a high strength. Further, in the case of the spring back method, a suction time (suction force) cannot be adjusted and hence, it is difficult to perform a low speed operation, thus having a problem that a transfer liquid generates foam or cannot be sucked.

The present invention has been made under such circumstances, and it is an object of the present invention to provide a reciprocating pump where a diaphragm is directly driven by working air at the time of discharging a transfer fluid, and the diaphragm is indirectly driven by way of a driving means at the time of sucking the transfer fluid so that a constant discharge pressure (the linearity of a discharge amount) is ensured at the time of performing the discharge operation, and a low speed operation can be performed with a smaller amount of working air without generating a negative pressure and a load on the diaphragm caused by the spring back at the time of performing the sucking operation.

### SUMMARY OF THE INVENTION

A reciprocating pump according to the present invention includes: a pump head having an inner space; a diaphragm configured to partition the inner space of the pump head into a pump chamber into which a transfer fluid is to be introduced and a working chamber into which working air is to be introduced; a driving means including a reciprocating member coupled to the diaphragm, the driving means being capable of driving the reciprocating member with the working air at least in a direction that the diaphragm is retracted; and a working air switching means configured to allow the working air to be introduced into the working chamber so as to cause the diaphragm to advance, thus causing the transfer fluid to be discharged from the pump chamber, and configured to allow the working air to be supplied to the driving means so as to drive the reciprocating member, thus causing the diaphragm to be retracted so as to allow the transfer fluid to be sucked into the pump chamber.

In one embodiment of the present invention, the pump head has a first vent opening which communicates with the working chamber, the driving means has a second vent opening which allows the working air to be introduced and exhausted therethrough, and the working air switching means includes a first working valve and a second working valve, the first working valve allowing the working air to be supplied from an air supply source to the first vent opening, and allowing the working air to be exhausted from the first vent opening, and the second working valve allowing the working air to be supplied from the air supply source to the second vent opening, and allowing the working air to be exhausted from the second vent opening.

In another embodiment of the present invention, the pump head includes: a suction port which allows the transfer fluid to be introduced into the pump chamber therethrough; a discharge port which allows the transfer fluid to be discharged from the pump chamber therethrough; and an exhaust port which allows a gas in the pump chamber to be exhausted therethrough, wherein the reciprocating pump further includes: a suction valve provided upstream of the suction port; a discharge valve provided downstream of the discharge port; and an exhaust valve provided downstream of the exhaust port.

In still another embodiment of the present invention, the reciprocating pump further includes a control unit configured to control operations of the first working valve, the second working valve, the suction valve, the discharge valve, and the exhaust valve, wherein the control unit brings at least one of the discharge valve and the exhaust valve into an open state with a delay from a timing at which the control unit brings the first working valve into an open state.

In still another embodiment of the present invention, the control unit brings the second working valve into a closed state with a delay from a timing at which the control unit brings the suction valve into a closed state.

In still another embodiment of the present invention, the driving means is formed of an air cylinder.

According to the present invention, the linearity of the discharge amount is ensured at the time of performing a discharge operation, and a low speed operation can be performed with a smaller amount of working air without generating a negative pressure and a load on a diaphragm caused by the spring back at the time of performing a sucking operation.

### BRIEF DESCRIPTION OF THE DRAWINGS

FIG. 1 is an explanatory view schematically showing the overall configuration of a liquid feed system which uses a reciprocating pump according to one embodiment of the present invention;

FIG. 2 is an explanatory view schematically showing the overall configuration of the liquid feed system; and

FIG. 3 is a time chart showing the operation of the reciprocating pump of the liquid feed system.

### DETAILED DESCRIPTION OF THE PREFERRED EMBODIMENT

Hereinafter, a reciprocating pump according to an embodiment of the present invention is described in detail with reference to attached drawings. However, the embodiment described hereinafter does not limit the invention according to respective claims. Further, it is not necessarily the case that all combinations of features described in the embodiment are indispensable as a solving means of the invention.

### [Configuration of Liquid Feed System]

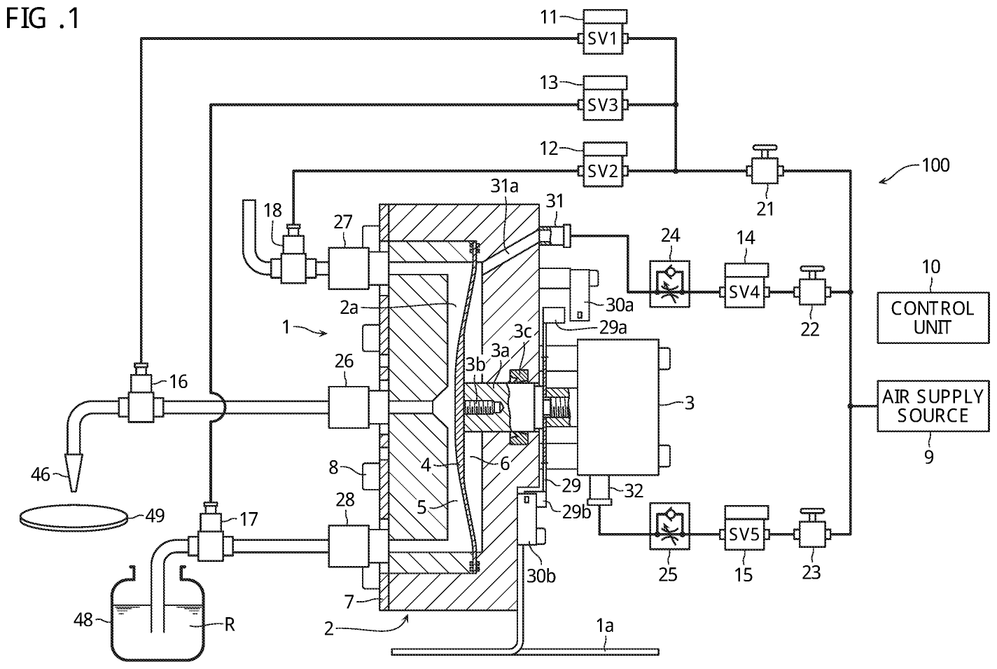

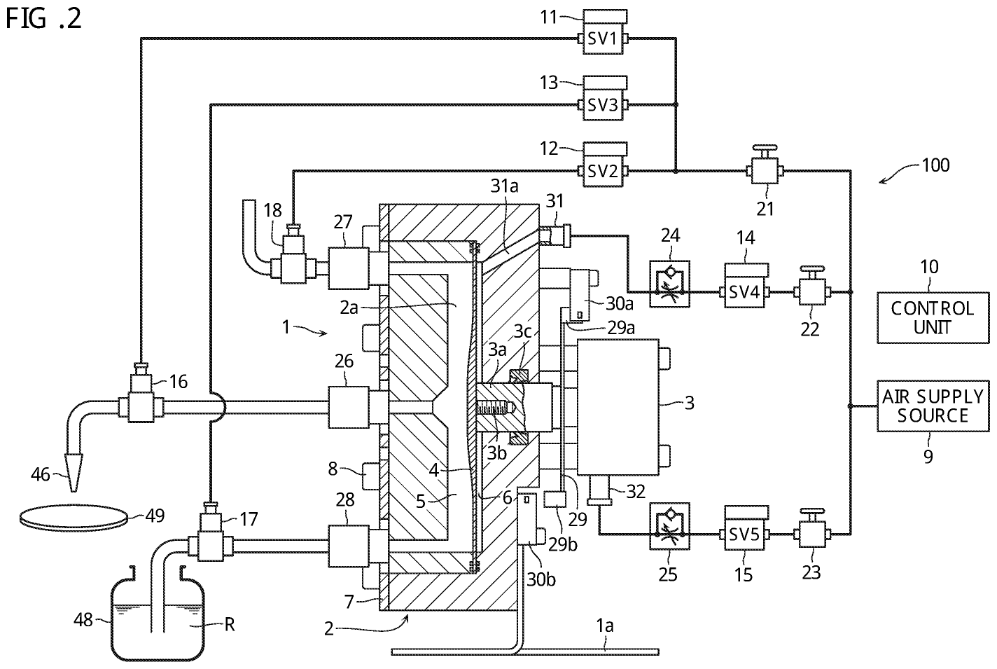

As shown in FIG. 1 and FIG. 2, a liquid feed system 100 includes a metering pump 1 as a reciprocating pump according to this embodiment, and a control unit 10 which controls the operation of the entire metering pump 1. The metering pump 1 includes a pump head 2 and an air cylinder 3 as a driving means which is mounted on the back surface side of the pump head 2.

The metering pump 1 of this embodiment feeds a resist R to be applied by coating to the upper surface of a semiconductor wafer 49 as a transfer fluid, for example. However, the transfer fluid is not limited to the resist R. FIG. 1 shows a state of respective components at the time of discharging the resist R, and FIG. 2 shows a state of the respective components at the time of sucking the resist R.

The pump head 2 is disposed above a pump base 1a, and has an inner space 2a therein. A diaphragm 4 is disposed in the inner space 2a. The diaphragm 4 is formed of an elastic member made of rubber, elastomer or the like. The diaphragm 4 partitions the inner space 2a of the pump head 2 into a pump chamber 5, into which the resist R is to be introduced, and a working chamber 6, into which working air is to be introduced. A head cover 7 is mounted on the front surface side of the pump head 2 by bolts 8. A discharge port 26, an exhaust port 27, and a suction port 28 are disposed on the front surface side of the pump head 2 with the head cover 7 interposed between these ports and the pump head 2.

The suction port 28 allows a resist R stored in a resist bottle 48, for example, to be introduced into the pump chamber 5 through an air operated valve (suction valve) 17, which is driven by air supplied from a third solenoid valve (SV3) 13. The discharge port 26 allows the resist R introduced into the pump chamber 5 to be discharged toward a nozzle 46 through an air operated valve (discharge valve) 16 which is driven by air supplied from a first solenoid valve (SV1) 11.

Further, the exhaust port 27 allows a gas in air bubbles generated in the resist R or air bubbles in the pump chamber 5 to be exhausted to the outside through an air operated valve (exhaust valve) 18 which is driven by air supplied from a second solenoid valve 12. The first to third solenoid valves 11 to 13 are respectively connected to an air supply source 9 through a pressure regulating valve 21.

The air cylinder 3 includes a rod-shaped piston rod 3a at a center portion thereof. The piston rod 3a is airtightly slidable in the longitudinal direction of the pump head 2 by way of a seal bushing 3c. A movable bracket 29 is mounted on the proximal end side of the piston rod 3a. Shielding plates 29a, 29b are respectively provided to upper and lower end portions of the movable bracket 29. The movable bracket 29 moves in the longitudinal direction with the movement of the piston rod 3a in the longitudinal direction. The distal end side of the piston rod 3a is mounted on the center portion of the diaphragm 4 by a bolt 3b.

A photosensor (S1) 30a and a photosensor (S2) 30b are provided on the back surface side of the pump head 2. The photosensor (S1) 30a is installed at a position around the area where the shielding plate 29a reaches when the piston rod 3a moves backward. The photosensor (S2) 30b is installed at a position around the area where the shielding plate 29b reaches when the piston rod 3a moves forward.

A vent opening 31 is further provided at the upper portion of the pump head 2 on the back surface side. The vent opening 31 is provided for introducing and discharging working air into and from the working chamber 6 through a pressure regulating valve 22, a fourth solenoid valve (SV4) 14, forming a first working valve, and a speed controller 24. The vent opening 31 is connected to the working chamber 6 through a vent passage 31a so as to communicate with a portion of the working chamber 6 in the vicinity of the upper end of the working chamber 6, for example. The vent passage 31a extends in an inclined manner obliquely downward to the working chamber 6.

A vent opening 32 is provided at a lower portion of the air cylinder 3. The vent opening 32 is provided for introducing and discharging working air into and from the cylinder through a pressure regulating valve 23, a fifth solenoid valve (SV5) 15, forming a second working valve, and a speed controller 25. The respective pressure regulating valves 22, 23 are connected to the air supply source 9. Further, a mechanism not shown in the drawing is provided in the air cylinder 3. The mechanism is connected to the proximal end side of the piston rod 3a, and causes the piston rod 3a to retract with the introduction of working air from the vent opening 32. The fourth solenoid valve 14 and the fifth solenoid valve 15 form a working air switching means which switches working air.

The liquid feed system 100 which uses the metering pump 1 having such a configuration is configured such that, at the time of performing a discharge operation of a resist R with control of the control unit 10, working air is supplied to the working chamber 6 so that the working air directly causes the diaphragm 4 to displace forward. On the other hand, at the time of performing a sucking operation of a resist R, the piston rod 3a is moved backward by the air cylinder 3, thus causing the diaphragm 4 to return to an original position (pulling back the diaphragm 4).

Accordingly, at the time of performing a discharge operation, it is possible to discharge a resist R at a constant pressure (it is possible to ensure the linearity between the introduction amount of working air and the discharge amount of a resist R). Further, at the time of performing a sucking operation, a low speed operation can be realized with a small amount of working air supplied to the air cylinder 3 without generating a negative pressure. Further, a uniform pressure is applied to the entire diaphragm 4 at the time of performing a discharge operation, and the air cylinder 3 is used at the time of performing a sucking operation. Accordingly, there is no possibility that a load is generated on the diaphragm 4 due to the spring back and hence, durability of the diaphragm 4 can be improved.

### [Operation of Metering Pump]

Next, the operation of the metering pump 1 in the liquid feed system 100 is described.

In the description made hereinafter, an operation for 1 cycle starts from a standby state (a state shown in FIG. 2) where the pump chamber 5 is already filled with a resist R, and the diaphragm 4 is at the original position.

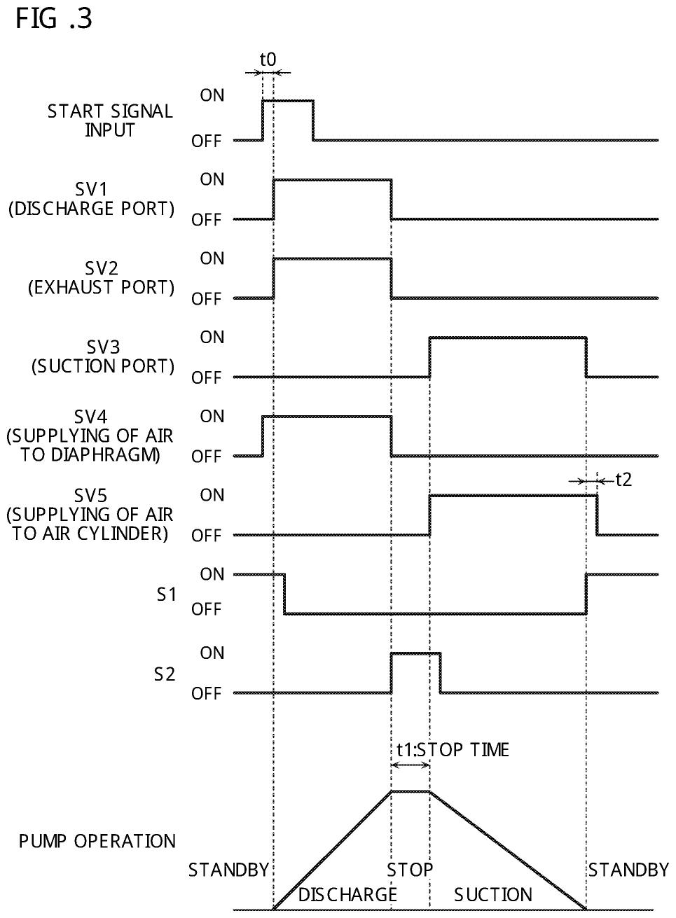

As shown in FIG. 3, when the control unit 10 receives a start signal (start signal input is brought into an ON state) in a standby state, the control unit 10 brings the fourth solenoid valve 14 into an ON state (the SV4 is brought into an ON state), and brings the first solenoid valve 11 or the second solenoid valve 12 into an ON state (the SV1 is brought into an ON state (or an SV2 is brought into an ON state)) with a delay of a predetermined time t0. With such operations, a discharge operation or a degassing operation is started. At the time of performing a normal discharge operation, the control unit 10 brings the first solenoid valve 11 into an ON state (the SV1 is brought into an ON state). On the other hand, at the time of performing a degassing operation, the control unit 10 brings the second solenoid valve 12 into an ON state (the SV2 is brought into an ON state).

When the fourth solenoid valve 14 is brought into an ON state, working air supplied from the air supply source 9 to the fourth solenoid valve 14 through the pressure regulating valve 22 is supplied into the working chamber 6 from the vent opening 31 in a state where the flow rate of the working air is adjusted by the speed controller 24. On the other hand, working air in the air cylinder 3 is discharged from the fifth solenoid valve 15 through the vent opening 32 and the speed controller 25. With such operations, the diaphragm 4 is expanded and displaced toward the pump chamber 5 side.

When the first solenoid valve 11 is brought into an ON state in the discharge operation, air supplied from the air supply source 9 to the first solenoid valve 11 through the pressure regulating valve 21 brings the air operated valve 16 into an ON state, thus making the discharge port 26 and the nozzle 46 communicate with each other. Further, when the second solenoid valve 12 is brought into an ON state in the degassing operation, air supplied from the air supply source 9 to the second solenoid valve 12 through the pressure regulating valve 21 brings the air operated valve 18 into an ON state, thus bringing the exhaust port 27 into an open state.

With such operations, at the time of performing the discharge operation, the resist R of an amount corresponding to the volume by which the diaphragm 4 is displaced into the pump chamber 5 is discharged (applied by coating) to the upper surface of the semiconductor wafer 49 from the pump chamber 5 through the discharge port 26, the air operated valve 16, and the nozzle 46. Further, at the time of performing a degassing operation, a gas or a resist R of an amount corresponding to the volume by which the diaphragm 4 is displaced into the pump chamber 5 is discharged to the outside from the pump chamber 5 through the exhaust port 27 and the air operated valve 18.

In performing a normal discharge operation, the timing at which the first solenoid valve 11 is brought into an ON state is delayed for a predetermined time of t0, for example, with respect to the timing at which the fourth solenoid valve 14 is brought into an ON state. With such an operation, discharging a resist R at a constant speed can be realized. Further, in performing a degassing operation, in the same manner as the above, the timing at which the second solenoid valve 12 is brought into an ON state is delayed for a predetermined time of t0 with respect to the timing at which the fourth solenoid valve 14 is brought into an ON state. With such an operation, it is possible to improve ease of discharge of a gas.

In the discharge operation or the degassing operation, at the timing when the shielding plate 29b of the movable bracket 29, which is mounted on the piston rod 3a of the air cylinder 3, is detected by the photosensor 30b (the S2 is brought into an ON state) (at the timing when the shielding plate 29b passes through the photosensor 30b), the control unit 10 brings the first solenoid valve 11 (or the second solenoid valve 12) and the fourth solenoid valve 14 into an OFF state (the SV1 is brought into an OFF state (or the SV2 is brought into an OFF state) and the SV4 is brought into an OFF state).

When the first solenoid valve 11 is brought into an OFF state, air being supplied to the air operated valve 16 is stopped so that the air operated valve 16 is brought into an OFF state, thus closing the communication between the discharge port 26 and the nozzle 46. Further, when the second solenoid valve 12 is brought into an OFF state, air being supplied to the air operated valve 18 is stopped so that the air operated valve 18 is brought into an OFF state, thus bringing the exhaust port 27 into a closed state.

Further, when the fourth solenoid valve 14 is brought into an OFF state, working air being supplied from the air supply source 9 to the fourth solenoid valve 14 through the pressure regulating valve 22 is stopped. Accordingly, a state is brought about where working air in the working chamber 6 can be discharged from the fourth solenoid valve 14 through the vent opening 31 and the speed controller 24.

With such operations, the diaphragm 4 is stopped in a state where the diaphragm 4 is expanded the most toward the pump chamber 5 side. Even if the shielding plate 29b is not detected by the photosensor 30b, by setting an input time (a time from the start of the discharge operation or the like, for example) of a detection signal in advance in the control unit 10, it is also possible to desirably stop the diaphragm 4. Adjusting the input time as described above allows the adjustment of the discharge amount of a resist R.

Thereafter, after the diaphragm 4 is stopped for the predetermined time t1, the control unit 10 brings the third solenoid valve 13 and the fifth solenoid valve 15 into an ON state (the SV3 is brought into an ON state and the SV5 is brought into an ON state). With such operations, a sucking operation is started. When the third solenoid valve 13 is brought into an ON state in the sucking operation, air supplied from the air supply source 9 to the third solenoid valve 13 through the pressure regulating valve 21 brings the air operated valve 17 into an ON state, thus making the suction port 28 and the resist bottle 48 communicate with each other.

Further, when the fifth solenoid valve 15 is brought into an ON state in the sucking operation, working air supplied from the air supply source 9 to the fifth solenoid valve 15 through the pressure regulating valve 23 is supplied into the air cylinder 3 from the vent opening 32 in a state where the flow rate of the working air is adjusted by the speed controller 25. On the other hand, working air in the working chamber 6 is discharged from the fourth solenoid valve 14 through the vent opening 31 and the speed controller 24. With such operations, the piston rod 3a moves backward so that the diaphragm 4 is pulled back toward the working chamber 6 side. With such operations, in performing a sucking operation, a resist R of an amount corresponding to the volume by which the diaphragm 4 is returned to the working chamber 6 side is introduced into the pump chamber 5 from the resist bottle 48 through the air operated valve 17 and the suction port 28.

In the sucking operation, at the timing when the shielding plate 29a of the movable bracket 29, which is mounted on the piston rod 3a of the air cylinder 3 is detected by the photosensor 30a (the S1 is brought into an ON state) (at the timing when the shielding plate 29a passes through the photosensor 30a), the control unit 10 brings the third solenoid valve 13 into an OFF state (the SV3 is brought into an OFF state). Thereafter, the control unit 10 brings the fifth solenoid valve 15 into an OFF state (the SV5 is brought into an OFF state) with a delay of a predetermined time t2. With such operations, the liquid feed system 100 is brought into a standby state again.

By delaying the timing at which the fifth solenoid valve 15 is brought into an OFF state for the predetermined time t2 with respect to the timing at which the third solenoid valve 13 is brought into an OFF state, it is possible to prevent the original position of the diaphragm 4 from being displaced forward due to the restoring force of the diaphragm 4. If the timing at which the fifth solenoid valve 15 is brought into an OFF state is set substantially equal to or earlier than the timing at which the third solenoid valve 13 is brought into an OFF state, the original position of the diaphragm 4 is displaced forward. The operations of the metering pump 1 for one cycle are completed as described above.

Each of the above-mentioned predetermined times t0 to t2 can be desirably set. Further, in the above-mentioned discharge operation and sucking operation of the metering pump 1, the control unit 10 can desirably change the discharging speed (mL/s) and the suction speed (mL/s) of the metering pump 1 by adjusting the pressure of air to be supplied to the pressure regulating valves 21 to 23 and by adjusting the flow rate of air to be supplied to the speed controllers 24, 25.

The embodiment of the present invention has been described heretofore. However, the embodiment is merely given for the sake of example, and does not intend to limit the scope of the invention. The novel embodiment can be carried out in other various modes, and various omissions, replacements, and changes may be made thereto without departing from the gist of the invention. These embodiments to which the omissions, replacements or change are made, and modifications of the embodiments are also included in the scope and the gist of the invention, and are included in the scope of the invention described in WHAT IS CLAIMED IS and an equivalent of the invention.

What is claimed is:

1. A reciprocating pump comprising:
a pump head having an inner space;
a diaphragm configured to partition the inner space of the pump head into a pump chamber into which a transfer fluid is to be introduced and a working chamber into which working air is to be introduced;
a driving means including a reciprocating member coupled to the diaphragm, the driving means being capable of driving the reciprocating member with the working air at least in a direction that the diaphragm is retracted; and
a working air switching means configured to allow the working air to be introduced into the working chamber so as to cause the diaphragm to advance, thus causing the transfer fluid to be discharged from the pump chamber, and configured to allow the working air to be supplied to the driving means so as to drive the reciprocating member, thus causing the diaphragm to be retracted so as to allow the transfer fluid to be sucked into the pump chamber.

2. The reciprocating pump according to claim 1, wherein
the pump head has a first vent opening which communicates with the working chamber,
the driving means has a second vent opening which allows the working air to be introduced and exhausted therethrough, and
the working air switching means includes a first working valve and a second working valve, the first working valve allowing the working air to be supplied from an air supply source to the first vent opening, and allowing the working air to be exhausted from the first vent opening, and the second working valve allowing the working air to be supplied from the air supply source to the second vent opening, and allowing the working air to be exhausted from the second vent opening.

3. The reciprocating pump according to claim 2, wherein
the pump head includes:
a suction port which allows the transfer fluid to be introduced into the pump chamber therethrough;
a discharge port which allows the transfer fluid to be discharged from the pump chamber therethrough; and
an exhaust port which allows a gas in the pump chamber to be exhausted therethrough, wherein
the reciprocating pump further comprises:
a suction valve provided upstream of the suction port;
a discharge valve provided downstream of the discharge port; and
an exhaust valve provided downstream of the exhaust port.

4. The reciprocating pump according to claim 3, further comprising a control unit configured to control operations of the first working valve, the second working valve, the suction valve, the discharge valve, and the exhaust valve, wherein
the control unit brings at least one of the discharge valve and the exhaust valve into an open state with a delay from a timing at which the control unit brings the first working valve into an open state.

5. The reciprocating pump according to claim 4, wherein
the control unit brings the second working valve into a closed state with a delay from a timing at which the control unit brings the suction valve into a closed state.

6. The reciprocating pump according to claim 1, wherein
the driving means is formed of an air cylinder.
